(19) United States
(12) Patent Application Publication
(10) Pub. No.: US 2008/0057622 A1
(43) Pub. Date: Mar. 6, 2008

(54) Map type semiconductor package

(75) Inventor: Wen-Jeng Fan, Hsinchu (TW)

Correspondence Address: TROXELL LAW OFFICE PLLC, SUITE 1404, 5205 LEESBURG PIKE, FALLS CHURCH, VA, 22041, US

(73) Assignee: Powertech Technology Inc.

(21) Appl. No.: 11/514,350

(22) Filed: Sep. 1, 2006

(51) Int. Cl. H01L 21/00

(52) U.S. Cl. 438/106

(57) ABSTRACT

A MAP (Mold-Array-Process) type semiconductor package mainly includes a chip carrier, at least a chip, and an encapsulant. The chip is disposed on the carrier and is electrically connected to the chip carrier. The encapsulant completely covers the upper surface of the chip carrier and encapsulates the chip. Therein, the encapsulant has two mold-flow constraining portions adjacent two opposite sides of the encapsulant, which are lower than the central top surface of the encapsulant and vertically aligned to the corresponding sawed sides of the chip carrier. Therefore, by changing the shape of the encapsulant, the mold flows on the chip and at the sides of the chip carrier will be the balanced to solve encapsulated bubble(s) formed on the rear side of the chip during MAP packaging, and disposition of conventional barrier components will be eliminated.

### FIELD OF THE INVENTION

The present invention relates to a semiconductor device, and more particularly to a MAP (Mold Array process) type semiconductor package and its manufacturing process.

### BACKGROUND OF THE INVENTION

In semiconductor packaging, implementation of Mold Array Process (MAP) can greatly reduce the molding cost and increase the packaging efficiency. A substrate strip includes a plurality of chip carriers (or called substrate units). After die attachment, an encapsulant covers most of the surface of the substrate strip by molding. After package saw, the sawed sides between the chip carriers including the encapsulant are cut through, a plurality of individual MAP packages are formed.

As shown in FIG. 1, a well-known MAP semiconductor package 100 includes a chip carrier 110, a chip 120, and an encapsulant 130 where the encapsulant 130 has four sawed sides which are vertical along the sawed sides of the chip carriers 110. The chip 120 is disposed on the chip carrier 110. The bonding pads 121 of the chip 120 are electrically connected to the chip carrier 110 by a plurality of bonding wires 140. The encapsulant 130 is formed on the chip carrier by molding to completely cover its upper surface. A plurality of external terminals 150 such as solder balls are disposed to the lower surface of the chip carrier 110. However, encapsulated bubbles 131 are easily formed on the rear side of the chip 120. As shown in FIG. 2, a plurality of chip carriers 110 are integrally connected to one another in an array to form a substrate strip during manufacturing processes. During molding in MAP, the precursor of the encapsulant 130 will cover most of the chip carriers 110 along the mold flow direction 132. However, the chips 120 on the chip carriers 110 will hinder the filling speed of the encapsulant 130. Therefore, the filling speed of the precursor of the encapsulant 130 at central portions of the chip carriers 110 will be slower than the one at the sides of chip carriers 110. Especially, the precursor of the encapsulant 130 reaches the chip 120 at the far end of the substrate strip, then the differences of the covering edges on the top of the chips 120 and at the sides of the chip carriers 110 become greater. The air at the rear sides of the chips 120 could not be expelled in time, and encapsulated bubbles 131 are trapped inside the encapsulant 130 during MAP.

A known solution to solve the issue of the encapsulated bubbles of MAP is disclosed in Taiwan Patent No. I240395, entitled “Encapsulating method on an array substrate by molding”. There are a plurality of obstructions disposed on the upper surface of each chip carrier along the cutting lines to slow down the mold filling speed at the sides of the chips during MAP for balancing the mold flow. The mold filling speeds on the top of the chip and at the sides of the chip will be the same to avoid encapsulated bubbles. However, the obstructions are additional components in conventional MAP method, that will increase the complexity of packaging process as well as the packaging cost. The thinner the obstructions is, the weaker the balance effect of mold flow is.

### SUMMARY OF THE INVENTION

The main purpose of the present invention is to provide a MAP type semiconductor package and its manufacturing process to balance mold flow speed at the center and at the sides of the chip carrier without encapsulated bubbles and, moreover, without the obstructions as mentioned above.

According to the present invention, a MAP type semiconductor package includes a chip carrier, at least a chip, and an encapsulant where the chip carrier has an upper surface, a lower surface, and a plurality of sawed sides between the upper and the lower surfaces. The chip is disposed on the upper surface of the chip carrier and is electrically connected to the chip carrier. The encapsulant is made by molding and completely covers the upper surface of the chip carrier and encapsulates the chip where two mold-flow constraining portions are formed adjacent two opposite sides of the encapsulant. The mold-flow constraining portions are lower than the central top surface of the encapsulant and are vertically aligned to the corresponding sawed sides of the chip carrier.

### DESCRIPTION OF THE DRAWINGS

FIG. 1 is a cross-sectional view of a well-known MAP type semiconductor package.

FIG. 2 is a top view of a substrate strip including a plurality of chip carriers of the packages to illustrate the differences of the mold filling speeds during MAP.

FIG. 3 is a cross-sectional view of a MAP type semiconductor package according to the first embodiment of the present invention.

FIG. 4 is a top view of the package according to the first embodiment of the present invention.

FIG. 5A to 5D are the cross-sectional views of the chip carrier of the package during MAP according to the first embodiment of the present invention.

FIG. 6 is a top view a substrate strip to illustrate the mold filling speed on a plurality of chip carriers of the packages according to the first embodiment of the present invention.

FIG. 7 is a cross-sectional view of a MAP type semiconductor package according to the second embodiment of the present invention.

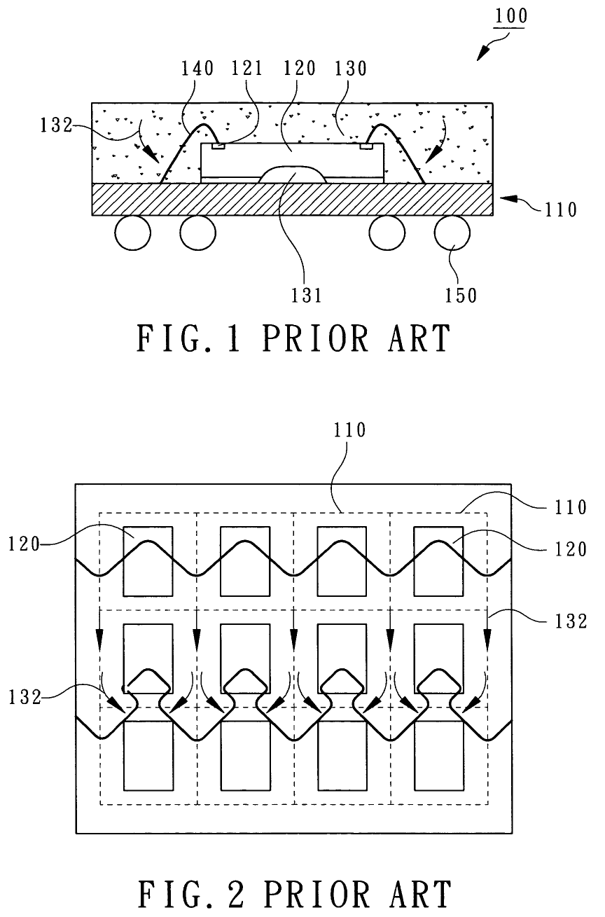

### DETAIL DESCRIPTION OF THE INVENTION

Please refer to the attached drawings, the present invention will be described by means of embodiment(s) below.

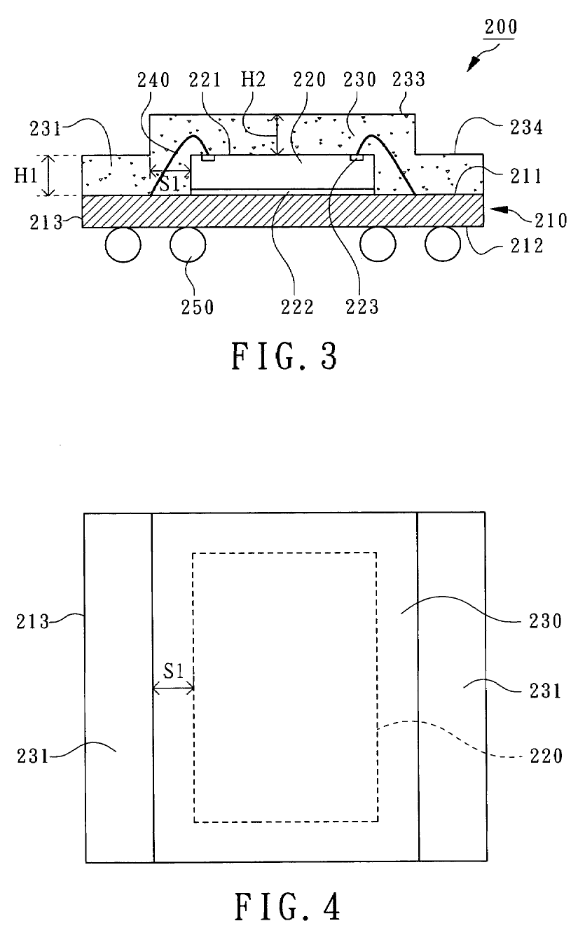

As shown in FIG. 3, a MAP type semiconductor package 200 is shown according to the first embodiment of the present invention, which includes a chip carrier 210, at least a chip 220, and an encapsulant 230 where the encapsulant 230 completely covers the upper surface of the chip carrier 210. The sidewalls of the encapsulant 230 are vertically aligned to the sawed sides 213 of the chip carrier 210.

The chip carrier 210 has an upper surface 211, a lower surface 212 and a plurality of sawed sides 213 between the upper surface 211 and the lower surface 212. In this embodiment, the chip carrier 210 is probably a printed circuit board including circuit pattern and vias, or a ceramic printed circuit board, a QFN, SON leadframe, or a BCC metal carrier.

The chip 220 is disposed on the upper surface 211 of the chip carrier 210 and is electrically connected to the chip carrier 120 by a plurality of bonding wires 240 or flip-chip bonding. The chip 220 has an active surface 221 and a corresponding back surface 222 where a plurality of bonding pads 223 are formed on the active surface 221. In the present embodiment, the back surface 222 of the chip 220 is attached to the upper surface 211 of the chip carrier 210 or stacked on other chips (not shown in the figure), such that the active surface 221 of the chip 220 is away from the upper surface 211 of the chip carrier 210. The bonding wires 240 are formed by wire-bonding to electrically connect the bonding pads 223 to the inner fingers of the chip carrier 210.

The encapsulant 230 completely covers the upper surface 211 of the chip carrier 210 and encapsulated the chip 220 where the encapsulant 230 is formed by Mold Array Processes (MPA), as shown in FIG. 6. As shown in FIG. 3 and 4, the encapsulant 230 has two mold-flow constraining portions 231 formed adjacent two opposite sawed sides of the encapsulant 230 along the mold flow direction. The mold-flow constraining portions 231 are lower than the central top surface 233 of the encapsulant 230 and are vertically aligned to the corresponding sawed sides 213 of the chip carrier 210. In the present embodiment, the MAP type semiconductor package 200 is rectangular and the mold-flow constraining portions 231 are in strip. There is no mold-flow constraining portion 231 at the other two sides of the encapsulant 230. Preferably, as shown in FIG. 3 again, each mold-flow constraining portions 231 has an edge top surface 234 is lower than the central top surface 233 of the encapsulant 230. Usually the first height Hi from the upper surface 211 of the chip carrier 210 to the edge top surface 234 is approximately equal to the second height H2 from the active surface 221 of the chip 220 to the central top surface 233 of the encapsulant 230 so that the mold-flow constraining portions 231 can perform the effect of mold-flow constraining. As shown in FIG. 6, along the mold flow direction 232, the mold flow speed at the sides of the chip carriers 210 will be slowed down and be balanced with the one on the chip 220 (at the center of the chip carrier 210). Therefore, air will not be trapped at the rear side of the chip 220, especially at the far end of the substrate strip causing encapsulated bubbles.

The mold-flow constraining portions 231 will not extend onto the chip 220. There is spacing SI between each mold-flow constraining portion 231 and the adjacent sides of the chip 220, which is equal to or smaller than the first height H1 so that the encapsulant 330 has a hat-like cross section. The mold-flow constraining portions 231 have enough width to achieve constraining effect so that the mold flow speed at the sides of the chip carrier 210 and at the center of the chip carrier 210 will be the same.

Furthermore, the MAP type semiconductor package 200 further includes a plurality of external terminals 250 disposed on the lower surface 212 of the chip carrier 210. In the present embodiment, the external terminals 250 include solder balls.

Therefore, only the shape of the encapsulant 230 is changed without disposition additional component in the MAP type semiconductor package 200, the mold flow speeds at the sides of the chip carrier 210 and at the center of the chip carrier 210 will be balanced during MAP. No encapsulated bubbles will be formed on the rear side of the chip 220.

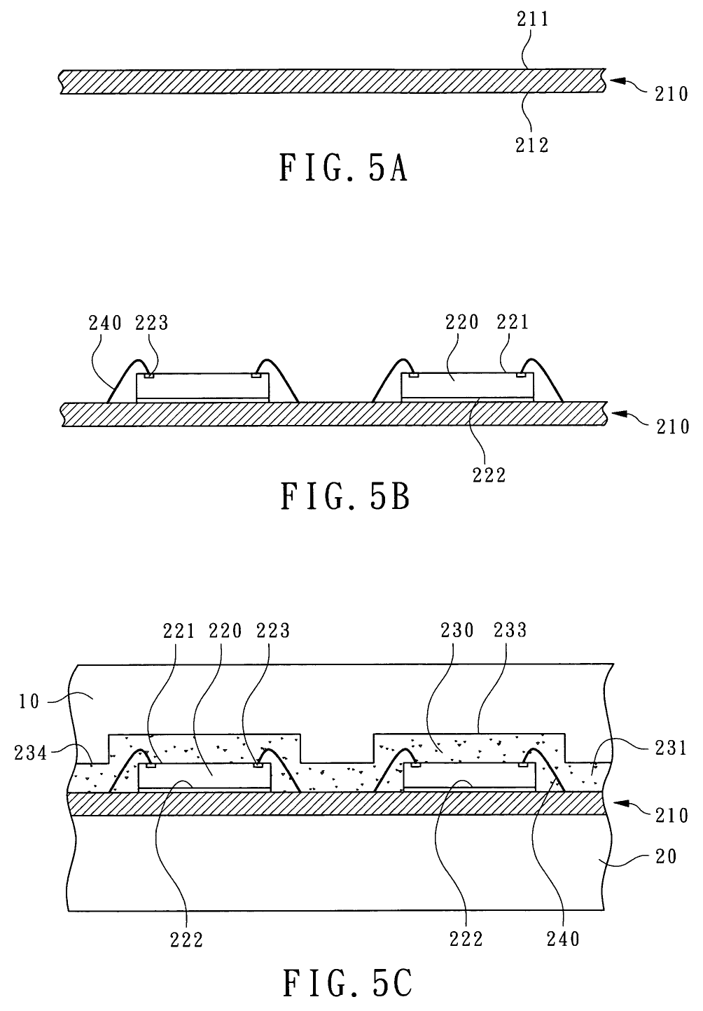

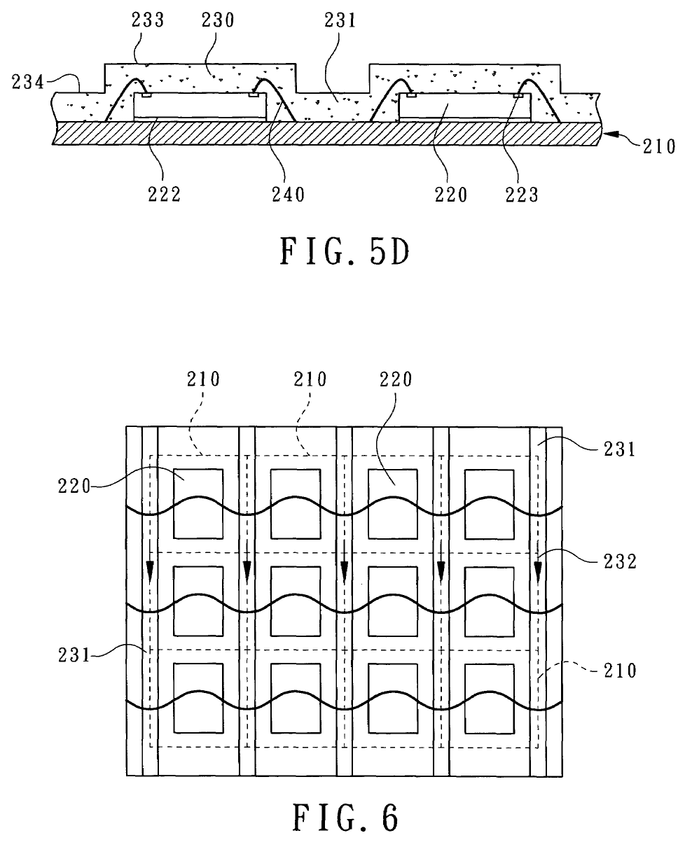

The MAP process for the semiconductor package 200 is further illustrated as follows. Firstly, as shown in FIG. 5A and FIG. 6, a substrate strip is provided, which includes a plurality of chip carriers 210 in an array which are integrally connected to one another. As shown in FIG. 5B, a plurality of chips 220 are disposed on the upper surfaces 211 of the chip carriers 210, and then electrically connected to the chip carriers 210 by a plurality of bonding wires 240. As shown in FIG. 5C and FIG. 6, a molding compound integrally including a plurality of encapsulant 230 is formed by transfer molding through the top molding tool 10 and the bottom molding tool 20. The top molding tool 10 has a non-planar mold cavity to form the encapsulants 230 which completely covers the upper surface 211 of the chip carrier 210 to encapsulate the chip 220. Each of the encapsulants 230 has two mold-flow constraining portions 231 connected to adjacent encapsulant 230 side by side where the mold-flow constraining portions 231 are lower than the central top surface 233 of the encapsulant 230 to reduce the mold flow speeds at the sides of the chip carriers 210 along the mold flow direction 232 (as shown in FIG. 6). The mold flow speeds at the sides of the chip carrier 210 will be slowed down to match the mold flow speeds at the chips 220 (the centers of the chip carriers 210). As shown in FIG. 5D, the encapsulated bubble issues can be solved without adding barriers or additional component in the MAP. Finally, the molding compound and the substrate strip are sawed to form a plurality of individual MAP type semiconductor packages 200, as shown in FIG. 3 and FIG. 4. Each chip carrier 210 has a plurality of sawed sides 213 between the upper surface 211 and the lower surface 232. Therefore, the mold-flow constraining portions 231 of the encapsulant 230 after singulation are vertically aligned to the corresponding sawed sides 213 of the corresponding chip carrier 210.

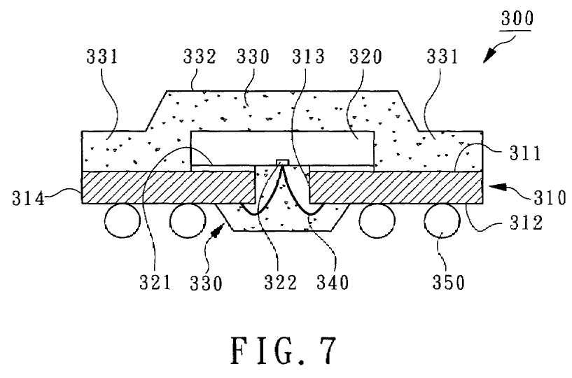

As shown in FIG. 7, a MAP type semiconductor package 300 is disclosed according to the second embodiment of the present invention, which includes a chip carrier 310, at least one chip 320 and an encapsulant 330 made by molding and sawing. The chip carrier 320 has an upper surface 311, a lower surface 312, and a plurality of sawed sides 314 between the upper surface 311 and the lower surface 312. The chip 320 is disposed on the upper surface 311 of the chip carrier 310 and is electrically connected to the chip carrier 310. In the present embodiment, the package type is a window BGA where the chip carrier 310 is a PWB, the active surface 321 of the chip 320 is attached to the upper surface 311 of the chip carrier 310 so that the plurality of bonding pads 322 are aligned within the slot 313 of the chip carrier 310. The bonding pads 322 are electrically connected to the chip carrier 310 by a plurality of bonding wires 340 passing through the slot 313.

The encapsulant 330 completely covers the upper surface 311 and fills in the slot 313 of the chip carrier 310 to encapsulate the chip 320 and the bonding wires 340. The encapsulant 330 has two mold-flow constraining portions 331 formed on the upper surface 311 of the chip carrier 310, which are lower than the central top surface 332 of the encapsulant 330 and vertically aligned to the corresponding sawed sides 314 of the chip carrier 310. Without adding barriers on the chip carrier 310, the mold flow speeds at the center of the chip 320 and at the sides of the chip 320 are balanced so that no encapsulated bubbles will be formed on the sides of the chip 320. Moreover, since the thickness of the encapsulant 330 at the mold-flow constraining portions 331 is thinner, the wearing of the sawing blades can be reduced.

The above description of embodiments of this invention is intended to be illustrative and not limiting. Other embodiments of this invention will be obvious to those skilled in the art in view of the above disclosure.

What is claimed is:

1. A MAP (Mold Array Process) type semiconductor package comprising:
a chip carrier having an upper surface, a lower surface, and a plurality of sawed sides between the upper and the lower surfaces;
at least a chip disposed on the upper surface of the chip carrier and electrically connected to the chip carrier; and
an encapsulant made by molding and completely covering the upper surface of the chip carrier and having two mold-flow constraining portions adjacent two opposite sides of the encapsulant, wherein the mold-flow constraining portions are lower than the central top surface of the encapsulant and are vertically aligned to the corresponding sawed sides of the chip carrier.

2. The semiconductor package of claim 1, wherein each of the mold-flow constraining portions has an edge top surface lower than the central top surface of the encapsulant, wherein a first height from the upper surface of the chip carrier to the edge top surfaces is approximately equal to a second height from the chip to the central top surface of the encapsulant.

3. The semiconductor package of claim 1, wherein the encapsulant is a cuboid including the two mold-flow constraining portions in thinner strips at its two opposite sides, and the other two sides have no mold-flow constraining portion.

4. The semiconductor package of claim 2, wherein the spacing between the mold-flow constraining portions and adjacent sides of the chip is equal to or smaller than the said first height.

5. The semiconductor package of claim 1, further including a plurality of bonding wires electrically connecting the chip and the chip carrier.

6. The semiconductor package of claim 5, wherein the active surface of the chip is attached to the upper surface of the chip carrier, wherein the chip has a plurality of bonding pads aligned within a slot of the chip carrier for electrical connection of the bonding wires through the slot.

7. The semiconductor package of claim 5, wherein the active surface of the chip is away from the upper surface of the chip carrier, wherein the bonding wires are formed between the upper surface and the active surface and are bonded to a plurality of 5 bonding pads of the chip.

8. The semiconductor package of claim 1, further including a plurality of external terminals on the lower surface of the chip carrier.

9. The semiconductor package of claim 8, wherein the external terminals includes solder balls.

10. A manufacturing process of MAP (Mold Array Process) type semiconductor packages, comprising the steps of:
providing a substrate strip including a plurality of chip carriers in an array and integrally connecting to one another, wherein each chip carrier has an upper surface and a lower surface;
disposing a plurality of chips on the upper surfaces of the chip carriers;
electrically connecting the chips and the chip carriers;
forming a molding compound on the substrate strip, wherein the molding compound completely covers the upper surfaces of the chip carriers and encapsulates the chips, the molding compound includes a plurality of encapsulants on the chip carriers respectively, each has two mold-flow constraining portions adjacent two opposite sides thereof, the mold-flow constraining portions are lower than the central top surfaces of the encapsulants; and
sawing the molding compound and the substrate strip such that each chip carrier has a plurality of sawed sides between the upper surface and the lower surface, each encapsulant is singulated and vertically aligned to the corresponding sawed sides of the corresponding chip carrier.

11. The process of claim 10, wherein each of the mold-flow constraining portions has an edge top surface lower than the central top surface of the encapsulant, wherein a first height from the upper surfaces of the chip carriers to the edge top surfaces is approximately equal to a second height from the chips to the central top surfaces of the encapsulants.

12. The process of claim 10, wherein the encapsulants are cuboids each including the two mold-flow constraining portions in thinner strips at its two opposite sides, and the other two sides have no mold-flow constraining portion.

13. The process of claim 12, wherein the spacing between the mold-flow constraining portions and adjacent sides of the chip is equal to or smaller than the said first height.

14. The process of claim 10, wherein the chips are electrically connected to the chip carriers by a plurality of boning wires.

15. The process of claim 14, wherein each chip carrier has a slot, the active surfaces of the chips are attached to the upper surfaces of the chip carriers such that a plurality of bonding pads of the chips are aligned within the slots of the corresponding chip carriers for electrical connection of the bonding wires through the slots.

16. The process of claim 14, wherein the active surfaces are away from the upper surfaces of the chip carriers, wherein the bonding wires are formed between the upper surfaces and the active surfaces and are bonded to a plurality of bonding pads of the chips.

17. The process of claim 10, further including the step of disposing a plurality of external terminals on the lower surfaces of the chip carriers.

18. The process of claim 17, wherein the external terminals includes solder balls.
